(19) United States
(12) Patent Application Publication
(10) Pub. No.: US 2003/0194857 A1
(43) Pub. Date: Oct. 16, 2003

(54) Method of making a semiconductor device that has copper damascene interconnects with enhanced electromigration reliability

(76) Inventors: Stefan Hau-Riege, Milpitas, CA (US); Christine Hau-Riege, Milpitas, CA (US); Jihperng Leu, Portland, OR (US); Kevin Fischer, Hillsboro, OR (US); Pei-Hua Wang, Portland, OR (US); Sean Hearne, Albuquerque, NM (US)

Correspondence Address: INTEL CORPORATION, P.O. BOX 5326, SANTA CLARA, CA, 95056-5326, US

(21) Appl. No.: 10/122,011

(22) Filed: Apr. 11, 2002

(51) Int. Cl. H01L 21/4763; H01L 21/44

(52) U.S. Cl. 438/637; 438/687; 438/927

(57) ABSTRACT

A method of making a semiconductor device is described. That method comprises forming a conductive layer that contacts a via, wherein the conductive layer includes a sufficient amount of a dopant, which will diffuse in the direction that is opposite to the direction in which electrons will flow through the conductive layer, to reduce the electromigration of the material that comprises the bulk of the conductive layer without significantly increasing the conductive layer's resistance.

### FIELD OF THE INVENTION

The present invention relates to a method of making semiconductor devices, in particular, devices that include copper damascene interconnects.

### BACKGROUND OF THE INVENTION

When making advanced semiconductor devices, copper interconnects may offer a number of advantages over those made from aluminum. For that reason, copper has become the material of choice for making such devices' interconnects. As device dimensions shrink so does conductor width—leading to higher resistance and current density. Increasing current density can increase the rate at which copper atoms are displaced when current passes through a copper conductor. Such electromigration can cause vacancies to accumulate, which may lead to voids. If the voids grow to a size that creates metal separation, they may cause an open-circuit failure.

One way to prevent electromigration from causing interconnect failure is to limit the amount of current that passes through the conductor. That solution to the electromigration problem is impractical, however, because devices will operate at progressively higher currents, even as they continue to shrink. As an alternative, interconnect reliability can be enhanced by doping the interconnect—as adding dopants to the conductor can reduce the rate at which copper diffuses.

When subject to electromigration stress, materials currently used to dope copper conductors to reduce electromigration drift along the conductor in the direction of electron flow—as shown in FIG. 1. Significant dopant depletion at the cathode end of the conductor can leave the host metal vulnerable to diffusion, also in the direction of electron flow. The resulting vacancies may lead to void formation, which may cause open-circuit failure. In addition, as atoms accumulate at the anode end of the conductor, excess metal may build up at that location, which can cause a short circuit.

Accordingly, there is a need for an improved process for making a semiconductor device that includes copper interconnects. There is a need for such a process that reduces electromigration by doping a copper conductor with a material that will not drain from the conductor's cathode end as electrons flow through it. The method of the present invention provides such a process.

### BRIEF DESCRIPTION OF THE DRAWINGS

FIG. 1 represents an overhead view of a conductive layer, shown contacting a pair of vias, that is doped with a material that diffuses along the conductive layer in the direction of electron flow.

FIG. 2 represents an overhead view of a conductive layer, shown contacting a pair of vias, that may be made when practicing the method of the present invention.

FIGS. 3a and 3b represent cross-sections of structures that may result after certain steps are used to make a semiconductor device using an embodiment of the method of the present invention.

FIG. 4 represents a cross-section of a structure that may result after certain steps are used to make a semiconductor device using a second embodiment of the method of the present invention.

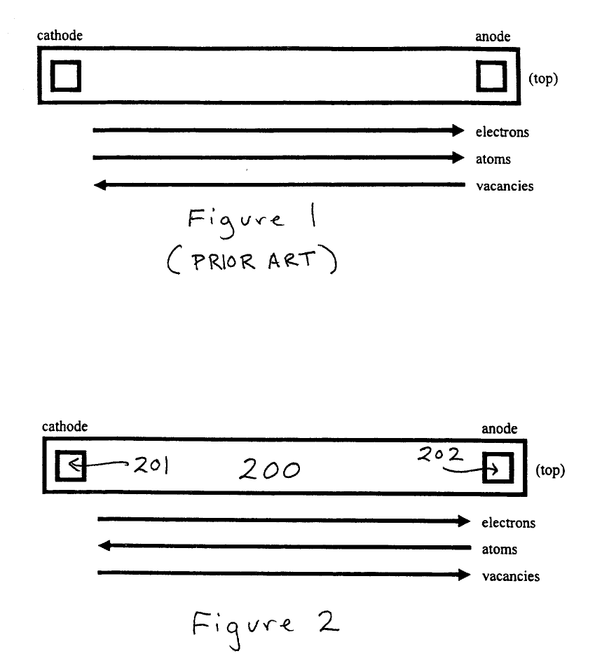

### DETAILED DESCRIPTION OF THE PRESENT INVENTION

A method for making a semiconductor device is described. That method comprises forming a conductive layer that contacts a via, wherein the conductive layer includes a sufficient amount of a dopant, which will diffuse in the direction that is opposite to the direction in which electrons will flow through the conductor, to reduce the electromigration of the material that comprises the bulk of the conductor without significantly increasing the conductor's resistance. In the method of the present invention, the via may be formed prior to forming the conductive layer on the via, or the conductive layer may be formed prior to forming the via on the conductive layer.

In the following description, a number of details are set forth to provide a thorough understanding of the present invention. It will be apparent to those skilled in the art, however, that the invention may be practiced in many ways other than those expressly described here. The invention is thus not limited by the specific details disclosed below.

The method of the present invention may be used in many contexts. In a preferred embodiment, it is used to improve the electromigration reliability of copper interconnects, which are formed using conventional damascene or dual damascene processes. As illustrated below, the method may be used when forming copper conductors that act as either enclosure structures (i.e., structures that ensure contact between a conductor and a via formed on it) or coverage structures (i.e., structures that ensure contact between a conductor and a via formed under it).

FIG. 2 represents an overhead view of a conductive layer, shown contacting a pair of vias, that may be made when practicing the method of the present invention. Conductive layer 200 includes a dopant (designated by “atoms” in the figure) that will diffuse in the direction (right to left) that is opposite to the direction in which electrons will flow through the conductor (left to right). Such “upwind” movement of the dopant atoms may serve to reduce the electromigration of the material that makes up the bulk of conductive layer 200, decreasing the rate at which vacancies develop due to that material's movement along that layer. As a result, vacancies may not accumulate fast enough to lead to voids that could cause open-circuit failure.

Conductive layer 200 may comprise copper and, as shown in FIG. 2, may be positioned below cathode via 201 and above anode via 202. When selecting an appropriate dopant for layer 200, the following should be considered. Metal atoms migrate via a vacancy exchange mechanism. When a bias is applied across a metal, a force—analogous to an electron “wind”—acts on it. That force is the sum of (1) an electrostatic force that acts toward the cathode (−), and (2) an electron scattering force that acts toward the anode (+). The direction that a metal atom will tend to move along a conductor, when electrons flow through it, will depend upon which of these forces dominate. That, in turn, will depend upon the scattering mechanism and the atomic valence of the metal.

The effect that the combination of these opposing forces has on a particular metal gives that metal an “effective valence,” which may be designated Z*. When Z* is positive, the metal will tend to move in a direction that is opposite to the direction of electron flow. When Z* is negative, the metal will tend to move in the same direction as the electrons. The following table, from H. Huntington, Diffusion in Solids, ed. A. S. Nowick, J. J. Burton, Academic Press (1975), p. 329, provides reported effective valence values for a number of elements (“f” is a correlation factor):

| Element | Z*/f |
|---|---|
| Al | −12 . . . −30 |
| Cu | −5 |
| Ag | −9 |
| Au | −8 |
| α-Fe | +2 |
| Co | +1.6 |
| Pt | +0.28 |
| β-Zr | +0.3 |

In a preferred embodiment, the dopant included in the conductive layer has a positive effective valence. Examples include iron, platinum, zirconium, and cobalt, but others may be used instead. For the dopant to reduce electromigration without also significantly increasing the conductive layer's resistance, it preferably should be included in the conductive layer at a concentration of between about 0.1 atomic % and about 10 atomic %, and more preferably between about 1 atomic % and about 10 atomic %.

The dopant may be integrated into conductive layer 200, as that layer is formed, or introduced into layer 200 after its formation. To integrate the dopant into layer 200 as that layer is being formed, doped seed layers, or a plating or sputtering process that adds dopants to the conductor as it is formed, may be used. When adding the dopant to conductive layer 200, after that layer has been formed, the dopant may be introduced into layer 200 in various ways. Examples include ion implanting the dopant into conductive layer 200, subjecting that layer to a gas that contains the dopant, or depositing a dopant containing layer onto that layer, then applying heat to cause the dopant to diffuse into layer 200.

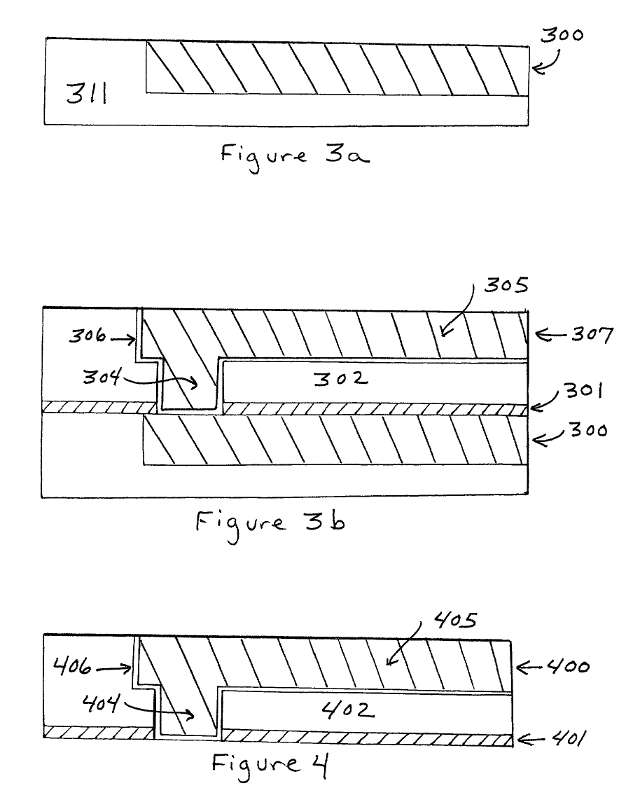

FIGS. 3a and 3b represent cross-sections of structures that may result after certain steps are used to make a semiconductor device using an embodiment of the method of the present invention. FIG. 3a shows conductive layer 300 formed within dielectric layer 311. Conductive layer 300 preferably includes copper. In accordance with the method of the present invention, a sufficient amount of a dopant—which will diffuse in the direction that is opposite to the direction of electron flow—is included in conductive layer 300 to reduce electromigration, without significantly raising resistance (i.e., without increasing resistance to an unacceptable level). As already indicated, conductive layer 300 may be doped with iron, platinum, zirconium, and/or cobalt—although other materials may be used instead.

The dopant may be integrated into layer 300 when layer 300 is formed by using doped seed layers, or a plating or sputtering process that adds dopants to the conductor as it is formed, as mentioned above. Alternatively, the dopant may be introduced afterwards, e.g., by bringing the dopant into contact with that layer, then applying heat to cause the dopant to diffuse into it. The dopant may be brought into contact with layer 300 in various ways. One way is simply to implant dopant ions into that layer using conventional ion implantation equipment and processes. The appropriate dose and energy to apply during the implantation process may depend upon layer 300's characteristics, the type of dopant used, and the function layer 300 will perform. Although ions preferably should be implanted into layer 300 prior to forming a barrier layer on it, it may be possible to dope the conductive layer by implanting ions through such a barrier layer—if a relatively high energy implant is performed, and if the barrier layer is relatively thin.

After ions are implanted into conductive layer 300, heat is applied to cause them to diffuse into that layer. The device should be heated at a sufficient temperature for a sufficient time to ensure that the dopant provides conductive layer 300 with improved electromigration characteristics without significantly raising its resistance. After completing all high temperature steps, the dopant concentration within conductive layer 300 preferably is at least about 0.1 atomic % and more preferably at least about 1 atomic %. Another way to introduce dopants into conductive layer 300 is to subject that layer to a gas that contains the dopant, using conventional furnace diffusion techniques.

Alternatively, dopant may be brought into contact with layer 300 by depositing a dopant containing layer onto layer 300. Such a dopant containing layer may include any of the dopants identified above, and may be formed using a conventional chemical vapor deposition process. After forming the dopant containing layer, heat is applied to cause the dopant to diffuse into layer 300. As with the ion implantation example described above, after the dopant diffuses into conductive layer 300, layer 300 should include the dopant at a concentration of between about 0.1 atomic % and about 10 atomic %, and more preferably a concentration that exceeds about 1 atomic %.

After conductive layer 300 is doped, barrier layer 301 and dielectric layer 302 may be formed on conductive layer 300, using conventional materials and process steps—as shown in FIG. 3b. Barrier layer 301 serves to minimize diffusion from conductive layer 300 into dielectric layer 302. Barrier layer 301 also acts as an etch stop to prevent a subsequent via etch step from exposing conductive layer 300 to subsequent cleaning steps. Barrier layer 301 preferably is made from silicon nitride, silicon oxynitride or silicon carbide, but may be made from other materials. Dielectric layer 302 may comprise silicon dioxide or a material that has a lower dielectric constant, e.g., SiOF, carbon doped oxide, or a porous oxide. Other low k materials that may be used to make dielectric layer 302 include organic polymers such as a polyimide, parylene, polyarylether, polynaphthalene, or polyquinoline.

In this embodiment of the present invention, via 304 and trench 305 are etched into dielectric layer 302 using conventional dual damascene techniques. When making a copper interconnect, barrier layer 306 may then be deposited onto the device. Barrier layer 306 may comprise tantalum, tantalum nitride or titanium nitride. The barrier layer will line via 304 and trench 305 and cover portions of dielectric layer 302. After lining via 304 and trench 305 with barrier layer 306, a seed layer (e.g., one including copper) may be deposited, followed by filling the via and trench with copper. A conventional copper electroplating process may be used. To produce the FIG. 3b structure, copper layer 307 is then polished (e.g., by applying a chemical mechanical polishing (“CMP”) step) until its surface is substantially flush with (or recessed slightly below) the surface of dielectric layer 302. (That polishing step may be followed by a standard cleaning process.) At the same time, the CMP step removes barrier layer 306 where it covers dielectric layer 302.

Other than doping the conductive layer as described above, the FIG. 3b structure may be formed using a conventional dual damascene process, which is well known to those skilled in the art. Conductive layer 300 serves as an enclosure structure for the via that is formed on top of it. In addition to doping conductive layer 300 with one or more of the materials specified above, that layer may be doped with a material (e.g., one with a negative effective valence) that will diffuse in the same direction as electrons will flow through that layer. When included, such a dopant should be added to layer 300 at a concentration that serves to retard electromigration to some extent without significantly increasing that layer's resistance. With this outcome in mind, this additional dopant, which may be derived, for example, from aluminum, cadmium, magnesium, tin and/or zirconium, preferably should be kept below about 1 atomic %. The optimum dopant concentration may depend upon layer 300's characteristics, the type of dopant used, and the function layer 300 will perform.

FIG. 4 represents a cross-section of a structure that may result after certain steps are used to make a semiconductor device using a second embodiment of the method of the present invention. Here, conductive layer 400 serves as a coverage structure. After dielectric layer 402 is formed on barrier layer 401, via 404 and trench 405 are etched into dielectric layer 402, lined with barrier layer 406, then filled with conductive layer 400. The resulting structure may be made using conventional processes that are well known to those skilled in the art.

When making the FIG. 4 structure, using the method of the present invention, conductive layer 400 preferably includes copper and a dopant, which will diffuse in the direction that is opposite to the direction of electron flow, that is present in a sufficient amount to reduce electromigration of copper. The dopant may be integrated into layer 400 when layer 400 is formed, or instead subsequently added to that layer, as described above. As with the enclosure structure described above, layer 400 may also be doped with a material that will diffuse in the same direction as the electrons will flow. A barrier layer, which may comprise silicon nitride or silicon carbide (not shown), may be subsequently formed on conductive layer 400 in the conventional manner.

In current processes, electromigration induced voiding in copper interconnects may occur primarily near the cathode via at the interface between the copper layer and an overlying barrier layer, while undesirable dopant accumulation may occur near the anode via. The process of the present invention improves interconnect electromigration by doping the conductive layer with a dopant that will diffuse in the direction that is opposite to the direction in which electrons will flow through the conductive layer. Such a dopant will not become depleted near the cathode while building up at the anode, as the device is operated. That, in turn, may slow down electromigration at the region most susceptible to open circuit failure, and may prevent short circuits from occurring. The method of the present invention thus may enable improved electromigration reliability, when compared to processes that dope conductive layers with conventionally used materials.

Features shown in the above referenced drawings are not intended to be drawn to scale, nor are they intended to be shown in precise positional relationship. Additional steps that may be used to make a semiconductor device using the described process have been omitted as they are not useful to describe aspects of the present invention.

Although the foregoing description has specified certain steps and materials that may be used to make a semiconductor device that includes a conductive layer, which has improved electromigration reliability, those skilled in the art will appreciate that many modifications and substitutions may be made. It is thus intended that all modifications, alterations, substitutions and additions to the specific embodiments described above be considered to fall within the spirit and scope of the invention as defined by the appended claims.

What is claimed is:

1. A method of making a semiconductor device comprising:
forming a conductive layer that contacts a via, wherein the conductive layer includes a sufficient amount of a dopant, which will diffuse in the direction that is opposite to the direction in which electrons will flow through the conductive layer, to reduce the electromigration of the material that comprises the bulk of the conductive layer without significantly increasing the conductive layer's resistance.

2. The method of claim 1 wherein the dopant has a positive effective valence.

3. The method of claim 2 wherein the dopant is selected from the group consisting of iron, platinum, zirconium, and cobalt.

4. The method of claim 1 wherein the dopant is included in the conductive layer at a concentration of between about 0.1 atomic % and about 10 atomic %.

5. The method of claim 1 wherein the conductive layer is positioned on top of the via.

6. The method of claim 1 wherein the via is positioned on top of the conductive layer.

7. The method of claim 1 wherein the conductive layer comprises copper.

8. The method of claim 1 wherein the conductive layer includes a second dopant that will diffuse in the same direction as electrons will flow through the conductive layer.

9. The method of claim 8 wherein the second dopant has a negative effective valence.

10. The method of claim 8 wherein the second dopant is selected from the group consisting of aluminum, cadmium, magnesium and tin.

11. A method of making a semiconductor device comprising:
forming on a substrate a conductive layer that includes a sufficient amount of a dopant, which will diffuse in the direction that is opposite to the direction in which electrons will flow through the conductive layer, to reduce the electromigration of the material that comprises the bulk of the conductive layer without significantly increasing the conductive layer's resistance; then
forming a dielectric layer on the conductive layer;
etching a via through the dielectric layer; and
filling the via with a conductive material.

12. The method of claim 11 further comprising:
forming a barrier layer on the conductive layer;
forming the dielectric layer on the barrier layer;
etching the via through a portion of the barrier layer, after etching the via through the dielectric layer, to expose a portion of the conductive layer; and then
filling the via with the conductive material.

13. The method of claim 12 wherein the conductive layer comprises copper, the dopant is selected from the group consisting of iron, platinum, zirconium, and cobalt, and the dopant is introduced into the conductive layer after the conductive layer is formed on the substrate.

14. The method of claim 13 wherein the dopant is introduced into the conductive layer by ion implanting the dopant into that layer, and wherein the dopant is included in the conductive layer at a concentration of between about 0.1 atomic % and about 10 atomic %.

15. The method of claim 12 wherein the conductive layer comprises copper and wherein the dopant is integrated into the conductive layer by adding the dopant to a seed layer, then forming the conductive layer on the seed layer.

16. The method of claim 11 wherein the conductive layer includes a second dopant that will diffuse in the same direction as electrons will flow through the conductive layer.

17. The method of claim 16 wherein the second dopant has a negative effective valence.

18. The method of claim 16 wherein the second dopant is selected from the group consisting of aluminum, cadmium, magnesium and tin.

19. A method of making a semiconductor device comprising:
forming a dielectric layer on a substrate;
etching a via through the dielectric layer and a trench into the dielectric layer; and
filling the via and trench with a conductive layer that includes a sufficient amount of a dopant, which will diffuse in the direction that is opposite to the direction in which electrons will flow through the conductive layer, to reduce the electromigration of the material that comprises the bulk of the conductive layer without significantly increasing the conductive layer's resistance.

20. The method of claim 19 wherein the conductive layer comprises copper, and the dopant is introduced into the conductive layer, after the conductive layer fills the via and trench, by ion implanting the dopant into that layer.

21. The method of claim 20 wherein the dopant is selected from the group consisting of iron, platinum, zirconium, and cobalt, and wherein the dopant is included in the conductive layer at a concentration of between about 0.1 atomic % and about 10 atomic %.

22. The method of claim 19 wherein the conductive layer includes a second dopant that will diffuse in the same direction as electrons will flow through the conductive layer.

23. The method of claim 22 wherein the second dopant has a negative effective valence.

24. The method of claim 22 wherein the second dopant is selected from the group consisting of aluminum, cadmium, magnesium and tin.
